(19) United States
(12) Patent Application Publication
(10) Pub. No.: US 2026/0304878 A1
(43) Pub. Date: Oct. 1, 2026

(54) DEVICES COMPRISING A THICK (AlzGa1-z)2O3 LAYER ON A (001) Ga2O3 SUBSTRATE USING A (AlxGa1-x)2O3 BUFFER LAYER, AND METHODS OF MAKING AND USE THEREOF

(71) Applicant: OHIO STATE INNOVATION FOUNDATION, Columbus, OH (US)

(72) Inventors: Hongping ZHAO, Dublin, OH (US); Lingyu MENG, Columbus, OH (US); Dong Su YU, Columbus, OH (US)

(21) Appl. No.: 19/477,599

(22) PCT Filed: Mar. 4, 2024
(86) PCT No.: PCT/US2024/018302

§ 371 Date: Oct. 22, 2025

Related U.S. Application Data
(60) Provisional application No. 63/463,931, filed on May 4, 2023.

(51) Int. Cl. H10D 62/80; C30B 25/18; C30B 29/14; C30B 29/22; C30B 29/68; H10P 14/20; H10P 14/24

(52) U.S. Cl. CPC H10D 62/875; C30B 25/18; C30B 29/14; C30B 29/22; C30B 29/68; H10P 14/24; H10P 14/2918; H10P 14/3434

(57) ABSTRACT

Disclosed herein are devices comprising a thick (Al_{z}Ga_{1-z})₂O₃ (e.g., Ga₂O₃) layer on a (001) Ga₂O₃ substrate using a (AlₓGa₁₋ₓ)₂O₃ buffer layer, and methods of making and use thereof. For example, disclosed herein are devices comprising a (001) Ga₂O₃ substrate, a first layer comprising (AlₓGa₁₋ₓ)₂O₃ where x is from 0 to 0.5, and a second layer comprising (Al_{z}Ga_{1-z})₂O₃ where is from 0 to 0.2 (e.g., Ga₂O₃), wherein the first layer is disposed on the substrate and the second layer is disposed on the first layer, such that the first layer is sandwiched between the substrate and the second layer, wherein the second layer has an average thickness of from 5 μm to 1000 μm (e.g., from 5 μm to 15 μm). Also disclosed herein are methods of making any of the devices disclosed herein, for example using metal organic chemical vapor deposition (MOCVD).

### CROSS-REFERENCE TO RELATED APPLICATIONS

This application claims the benefit of priority to U.S. Provisional Application No. 63/463,931 filed May 4, 2023, which is hereby incorporated herein by reference in its entirety.

### STATEMENT OF GOVERNMENT SUPPORT

This invention was made with government support under grant/contract number FA9950-18-1-0479 awarded by the Air Force Office of Scientific Research. The government has certain rights in the invention.

### BACKGROUND

Owing to its remarkable properties, such as a large energy bandgap (4.8 eV), controllable n-type doping, and a high predicted breakdown field strength (8 MV/cm), β-Ga₂O₃ is regarded as a promising semiconductor material for next-generation high-power electronic devices. In order to develop high-power electronic devices with even higher reverse breakdown voltage, a thick drift layer with smooth surface morphology and controllable low doping are needed. Therefore, growth of high quality thick β-Ga₂O₃ with relatively fast growth rates is needed, especially on (001) oriented β-Ga₂O₃ substrates. The compositions, methods, and devices discussed herein addresses these and other needs.

### SUMMARY

In accordance with the purposes of the disclosed compositions, methods, and devices as embodied and broadly described herein, the disclosed subject matter relates to devices comprising a thick (Al_{z}Ga_{1-z})₂O₃ (e.g., Ga₂O₃) layer on a (001) Ga₂O₃ substrate using a (AlₓGa₁₋ₓ)₂O₃ buffer layer, and methods of making and use thereof.

For example, disclosed herein are methods for developing thick β-Ga₂O₃ films on (001) Ga₂O₃ substrates using a (AlₓGa₁₋ₓ)₂O₃ buffer layer.

For example, disclosed herein are devices comprising a (001) Ga₂O₃ substrate. The devices further comprise a first layer comprising (AlₓGa₁₋ₓ)₂O₃ where x is from 0 to 0.5. The devices further comprise a second layer comprising (Al_{z}Ga_{1-z})₂O₃ where z is from 0 to 0.2. The first layer is disposed on the substrate and the second layer is disposed on the first layer, such that the first layer is sandwiched between the substrate and the second layer. In some examples, the second layer has an average thickness of from 5 μm to 1000 μm.

In some examples, the substrate comprises a (001) β-Ga₂O₃ substrate.

In some examples, the first layer comprises (AlₓGa₁₋ₓ)₂O₃ where x is from 0 to 0.3.

In some examples, the first layer has an average thickness of from 5 to 1000 nm, from 5 nm to 500 nm, from 10 nm to 100 nm, or from 15 to 25 nm.

In some examples, the second layer comprises Ga₂O₃. In some examples, the second layer comprises β-Ga₂O₃.

In some examples, the second layer has an average thickness of from 5 to 100 μm. In some examples, the second layer has an average thickness of from 5 to 15 μm. In some examples, the second layer has an average thickness of from 6 to 9 μm.

In some examples, the device comprises a (001) Ga₂O₃ substrate, a first layer comprising (AlₓGa₁₋ₓ)₂O₃ where x is from 0 to 0.5, and a second layer comprising Ga₂O₃, wherein the first layer is disposed on the substrate and the second layer is disposed on the first layer, such that the first layer is sandwiched between the substrate and the second layer, wherein the second layer has an average thickness of from 5 μm to 15 μm.

In some examples, the second layer has a surface roughness that is lower than the surface roughness of the same device in the absence of the first layer.

In some examples, the second layer is relatively smooth and/or substantially free of cracks.

In some examples, the device comprises an optical device, an electronic device, an optoelectronic device, or a combination thereof.

In some examples, the device comprises a lateral device, a vertical device, or a combination thereof.

Also disclosed herein are methods of making any of the devices described herein. For example, the methods can comprise depositing the first layer on the substrate and depositing the second layer on the first layer.

In some examples, the first layer and/or the second layer are deposited using metal organic chemical vapor deposition (MOCVD).

In some examples, the first layer is deposited using MOCVD using an Al-containing precursor, a Ga-containing precursor, an oxygen containing precursor, or a combination thereof.

In some examples, the first layer is deposited using MOCVD using an Al-containing precursor, a Ga-containing precursor, and an oxygen containing precursor. In some examples, the concentration of aluminum in the first layer can be controlled by controlling the concentration and/or ratio of the precursors, the temperature, the pressure, or a combination thereof.

In some examples, the method produces the first layer at a growth rate of from 100 to 2000 nm/hour. In some examples, the method produces the first layer at a growth rate of from 100 to 800 nm/hour, such as 400 nm/hr.

In some examples, the second layer is deposited using MOCVD using an Al-containing precursor, a Ga-containing precursor, an oxygen containing precursor, or a combination thereof.

In some examples, the second layer is deposited using MOCVD using a Ga-containing precursor and an oxygen containing precursor.

In some examples, the method produces the second layer at a growth rate of from 1 to 20 μm/hour. In some examples, the method produces the second layer at a growth rate of from 1 to 10 μm/hour, such as 3 μm/hour.

In some examples, the Al-containing precursor, the Ga-containing precursor, and/or the oxygen containing precursor independently comprise(s) a fluid, such as a gas.

In some examples, the Al-containing precursor comprises trimethyl aluminum (TMAl), triethyl aluminum (TEAl), or a combination thereof. In some examples, the Al-containing precursor comprises trimethylaluminum (TMAl).

In some examples, the Ga-containing precursor comprises trimethylgallium (TMGa), triethyl gallium (TEGa), or a combination thereof.

In some examples, the oxygen containing precursor comprises 02.

In some examples, the method further comprises introducing an additional precursor comprising a dopant, such that the first layer and/or the second layer further comprises the dopant. In some examples, the additional precursor is provided as a fluid, such as a gas. In some examples, the additional precursor comprises an n-type dopant, such as a silicon containing precursor.

In some examples, the Al-containing precursor, the Ga-containing precursor, the oxygen containing precursor, the additional precursor (when present), or a combination thereof are independently provided with a carrier gas. In some examples, the carrier gas comprises argon, helium, N₂, and the like, or combinations thereof.

In some examples, the method is conducted at a temperature of from 650-1100° C. and/or a pressure of from 5 to 600 torr. In some examples, the method is conducted at a temperature of from 650-1000° C. and/or a pressure of from 5 to 600 torr.

Additional advantages of the disclosed compositions, devices, and methods will be set forth in part in the description which follows, and in part will be obvious from the description. The advantages of the disclosed compositions, devices, and methods will be realized and attained by means of the elements and combinations particularly pointed out in the appended claims. It is to be understood that both the foregoing general description and the following detailed description are exemplary and explanatory only and are not restrictive of the disclosed devices and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1A. Surface SEM image of β-Ga₂O₃ film (9 μm) grown with TMGa on (001) Sn-doped β-Ga₂O₃ substrate: large field of view of cracking area. The film was grown with a growth rate of 3 m/hr without using AlGaO buffer layer.

FIG. 1B. Surface SEM image of β-Ga₂O₃ film (9 μm) grown with TMGa on (001) Sn-doped β-Ga₂O₃ substrate: large field of view of no-cracking area. The film was grown with a growth rate of 3 m/hr without using AlGaO buffer layer.

FIG. 1C. Surface SEM image of β-Ga₂O₃ film (9 μm) grown with TMGa on (001) Sn-doped β-Ga₂O₃ substrate: high magnification of cracking area. The film was grown with a growth rate of 3 m/hr without using AlGaO buffer layer.

FIG. 1D. Surface SEM image of β-Ga₂O₃ film (9 μm) grown with TMGa on (001) Sn-doped β-Ga₂O₃ substrate: high magnification of no-cracking area. The film was grown with a growth rate of 3 m/hr without using AlGaO buffer layer.

FIG. 2. Schematic of a relatively thick β-Ga₂O₃ film grown on (001) oriented β-Ga₂O₃ substrate using a thin β-(AlₓGa₁₋ₓ)₂O₃ buffer layer as buffer to suppress the cracking in the top Ga₂O₃ layer.

FIG. 3. Schematic of a β-Ga₂O₃ film grown on (001) oriented β-Ga₂O₃ substrates using a 20 nm thin β-(AlₓGa₁₋ₓ)₂O₃ buffer layer with varying Al composition between the β-Ga₂O₃ epi-layer and the substrate.

FIG. 4A. Optical macroscopic surface image of β-Ga₂O₃ films (6 μm) grown with TMGa on (001) β-Ga₂O₃ substrate with thin β-(AlₓGa₁₋ₓ)₂O₃ buffer layer with x=0%.

FIG. 4B. Optical macroscopic surface image of β-Ga₂O₃ films (6 μm) grown with TMGa on (001) β-Ga₂O₃ substrate with thin β-(AlₓGa₁₋ₓ)₂O₃ buffer layer with x=8%.

FIG. 4C. Optical macroscopic surface image of β-Ga₂O₃ films (6 μm) grown with TMGa on (001) β-Ga₂O₃ substrate with thin j-(AlₓGa₁₋ₓ)₂O₃ buffer layer with x=15%.

FIG. 4D. Optical macroscopic surface image of β-Ga₂O₃ films (6 μm) grown with TMGa on (001) β-Ga₂O₃ substrate with thin j-(AlₓGa₁₋ₓ)₂O₃ buffer layer with x=22%.

FIG. 4E. Optical macroscopic surface image of β-Ga₂O₃ films (6 μm) grown with TMGa on (001) β-Ga₂O₃ substrate with thin j-(AlₓGa₁₋ₓ)₂O₃ buffer layer with x=29%.

FIG. 5A. Optical macroscopic surface image of β-Ga₂O₃ film (9 μm) grown with TMGa on (001) β-Ga₂O₃ substrate with thin j-(AlₓGa₁₋ₓ)₂O₃ buffer layer with x=0%.

FIG. 5B. Optical macroscopic surface image of β-Ga₂O₃ film (9 μm) grown with TMGa on (001) β-Ga₂O₃ substrate with thin β-(AlₓGa₁₋ₓ)₂O₃ buffer layer with x=29%.

FIG. 6. Schematic of a ~6 μm β-Ga₂O₃ film grown on (001) oriented β-Ga₂O₃ substrate using a thin (AlₓGa₁₋ₓ)₂O₃ buffer layer.

FIG. 7. Optical macroscopic surface image of Ga₂O₃ film (~6 μm) grown with TMGa on (001) β-Ga₂O₃ substrate with a (AlₓGa₁₋ₓ)₂O₃ buffer layer.

FIG. 8. Optical macroscopic surface image of Ga₂O₃ film (~6 μm) grown with TMGa on (001) β-Ga₂O₃ substrate with a (AlₓGa₁₋ₓ)₂O₃ buffer layer. Two cracks were observed, which are indicated with arrows.

FIG. 9. SEM image of the surface of Ga₂O₃ film (~6 μm) grown with TMGa on (001) β-Ga₂O₃ substrate with a (AlₓGa₁₋ₓ)₂O₃ buffer layer.

FIG. 10. SEM image of the surface of Ga₂O₃ film (~6 μm) grown with TMGa on (001) β-Ga₂O₃ substrate with a (AlₓGa₁₋ₓ)₂O₃ buffer layer.

FIG. 11. AFM of the surface of Ga₂O₃ film (~6 μm) grown with TMGa on (001) 0-Ga₂O₃ substrate with a (AlₓGa₁₋ₓ)₂O₃ buffer layer.

### DETAILED DESCRIPTION

The compositions, methods, and devices described herein may be understood more readily by reference to the following detailed description of specific aspects of the disclosed subject matter and the Examples included therein.

Before the present compositions, methods, and devices are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Values can be expressed herein as an “average” value. “Average” generally refers to the statistical mean value.

By “substantially” is meant within 5%, e.g., within 4%, 3%, 2%, or 1%.

“Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

### Devices and Methods of Making and Use Thereof

Disclosed herein are devices comprising a thick (Al_{z}Ga_{1-z})₂O₃ layer on a (001) Ga₂O₃ substrate using a (AlₓGa₁₋ₓ)₂O₃ buffer layer, and methods of making and use thereof. For example, disclosed herein are devices comprising a thick Ga₂O₃ layer on a (001) Ga₂O₃ substrate using a (AlₓGa₁₋ₓ)₂O₃ buffer layer, and methods of making and use thereof.

For example, disclosed herein are devices comprising a (001) Ga₂O₃ substrate.

In some examples, the substrate comprises a (001) β-Ga₂O₃ substrate.

The devices further comprise a first layer comprising disposed on the substrate. The first layer comprises (AlₓGa₁₋ₓ)₂O₃ where x is from 0 to 0.5. For example, x is 0 or more (e.g., 0.01 or more, 0.02 or more, 0.03 or more, 0.04 or more, 0.05 or more, 0.06 or more, 0.07 or more, 0.08 or more, 0.09 or more, 0.10 or more, 0.11 or more, 0.12 or more, 0.13 or more, 0.14 or more, 0.15 or more, 0.16 or more, 0.17 or more, 0.18 or more, 0.19 or more, 0.20 or more, 0.21 or more, 0.22 or more, 0.23 or more, 0.24 or more, 0.25 or more, 0.26 or more, 0.27 or more, 0.28 or more, 0.29 or more, 0.30 or more, 0.31 or more, 0.32 or more, 0.33 or more, 0.34 or more, 0.35 or more, 0.36 or more, 0.37 or more, 0.38 or more, 0.39 or more, 0.40 or more, 0.41 or more, 0.42 or more, 0.43 or more, 0.44 or more, 0.45 or more, 0.46 or more, 0.47 or more, 0.48 or more, or 0.49 or more). In some examples, x is 0.5 or less (e.g., 0.49 or less, 0.48 or less, 0.47 or less, 0.46 or less, 0.45 or less, 0.44 or less, 0.43 or less, 0.42 or less, 0.41 or less, 0.40 or less, 0.39 or less, 0.38 or less, 0.37 or less, 0.36 or less, 0.35 or less, 0.34 or less, 0.33 or less, 0.32 or less, 0.31 or less, 0.30 or less, 0.29 or less, 0.28 or less, 0.27 or less, 0.26 or less, 0.25 or less, 0.24 or less, 0.23 or less, 0.22 or less, 0.21 or less, 0.20 or less, 0.19 or less, 0.18 or less, 0.17 or less, 0.16 or less, 0.15 or less, 0.14 or less, 0.13 or less, 0.12 or less, 0.11 or less, 0.10 or less, 0.09 or less, 0.08 or less, 0.07 or less, 0.06 or less, 0.05 or less, 0.04 or less, 0.03 or less, 0.02 or less, or 0.01 or less). The value of x can range from any of the minimum values described above to any of the maximum values described above. For example, x can be from 0 to 0.5 (e.g., from 0 to 0.25, from 0.25 to 0.5, from 0 to 0.1, from 0.1 to 0.2, from 0.2 to 0.3, from 0.3 to 0.4, from 0.4 to 0.5, from 0 to 0.4, from 0 to 0.3, from 0 to 0.2, from 0.1 to 0.5, from 0.2 to 0.5, from 0.3 to 0.5, or from 0.1 to 0.4). In some examples, the first layer comprises (AlₓGa₁₋ₓ)₂O₃ where x is from 0 to 0.3.

The first layer can, for example, have an average thickness of 5 nanometers (nm) or more (e.g., 10 nm or more, 15 nm or more, 20 nm or more, 25 nm or more, 30 nm or more, 35 nm or more, 40 nm or more, 45 nm or more, 50 nm or more, 60 nm or more, 70 nm or more, 80 nm or more, 90 nm or more, 100 nm or more, 125 nm or more, 150 nm or more, 175 nm or more, 200 nm or more, 225 nm or more, 250 nm or more, 300 nm or more, 350 nm or more, 400 nm or more, 450 nm or more, 500 nm or more, 550 nm or more, 600 nm or more, 650 nm or more, 700 nm or more, 750 nm or more, 800 nm or more, 850 nm or more, or 900 nm or more). In some examples, the first layer can have an average thickness of 1000 nm or less (e.g., 950 nm or less, 900 nm or less, 850 nm or less, 800 nm or less, 750 nm or less, 700 nm or less, 650 nm or less, 600 nm or less, 550 nm or less, 500 nm or less, 450 nm or less, 400 nm or less, 350 nm or less, 300 nm or less, 250 nm or less, 225 nm or less, 200 nm or less, 175 nm or less, 150 nm or less, 125 nm or less, 100 nm or less, 90 nm or less, 80 nm or less, 70 nm or less, 60 nm or less, 50 nm or less, 45 nm or less, 40 nm or less, 35 nm or less, 30 nm or less, 25 nm or less, 20 nm or less, 15 nm or less, or 10 nm or less). The average thickness of the first layer can range from any of the minimum values described above to any of the maximum values described above. For example, the first layer can have an average thickness of from 5 nm to 1000 nm (e.g., from 5 to 500 nm, from 500 nm to 1000 nm, from 5 to 250 nm, from 250 to 500 nm, from 500 nm to 750 nm, from 750 nm to 1000 nm, from 5 nm to 100 nm, from 100 nm to 200 nm, from 200 nm to 300 nm, from 300 nm to 400 nm, from 400 nm to 500 nm, from 500 to 600 nm, from 600 to 700 nm, from 700 to 800 nm, from 800 to 900 nm, from 900 to 1000 nm, from 5 nm to 900 nm, from 5 to 800 nm, from 5 to 700 nm, from 5 to 600 nm, from 5 nm to 400 nm, from 5 nm to 300 nm, from 5 nm to 200 nm, from 5 nm to 100 nm, from 5 nm to 50 nm, from 5 nm to 25 nm, from 10 to 1000 nm, from 25 to 1000 nm, from 50 to 1000 nm, from 100 to 1000 nm, from 200 to 1000 nm, from 300 to 1000 nm, from 400 to 1000 nm, from 600 to 1000 nm, from 700 to 1000 nm, from 800 to 1000 nm, from 10 to 900 nm, from 25 to 800 nm, from 10 nm to 500 nm, from 25 nm to 500 nm, from 50 to 500 nm, from 100 to 500 nm, from 200 to 500 nm, from 300 to 500 nm, from 10 nm to 450 nm, from 10 nm to 100 nm, or from 15 to 25 nm).

In some examples, the first layer comprises (AlₓGa₁₋ₓ)₂O₃ where x is from 0 to 0.5 and has an average thickness of from 5 to 500 nm. In some examples, the first layer comprises (AlₓGa₁₋ₓ)₂O₃ where x is from 0 to 0.5 and has an average thickness of from 10 to 100 nm. In some examples, the first layer comprises (AlₓGa₁₋ₓ)₂O₃ where x is from 0 to 0.5 and has an average thickness of from 15 to 25 nm.

In some examples, the first layer comprises (AlₓGa₁₋ₓ)₂O₃ where x is from 0 to 0.3 and has an average thickness of from 5 to 500 nm. In some examples, the first layer comprises (AlₓGa₁₋ₓ)₂O₃ where x is from 0 to 0.3 and has an average thickness of from 10 to 100 nm. In some examples, the first layer comprises (AlₓGa₁₋ₓ)₂O₃ where x is from 0 to 0.3 and has an average thickness of from 15 to 25 nm.

The devices further comprise a second layer wherein the second layer is disposed on the first layer, such that the first layer is sandwiched between the substrate and the second layer.

In some examples, the second layer comprises (Al_{z}Ga_{1-z})₂O₃ where z is from 0 to 0.2. For example, z is 0 or more (e.g., 0.01 or more, 0.02 or more, 0.03 or more, 0.04 or more, 0.05 or more, 0.06 or more, 0.07 or more, 0.08 or more, 0.09 or more, 0.10 or more, 0.11 or more, 0.12 or more, 0.13 or more, 0.14 or more, 0.15 or more, 0.16 or more, 0.17 or more, 0.18 or more, 0.19 or more). In some examples, z is 0.2 or less (e.g., 0.19 or less, 0.18 or less, 0.17 or less, 0.16 or less, 0.15 or less, 0.14 or less, 0.13 or less, 0.12 or less, 0.11 or less, 0.10 or less, 0.09 or less, 0.08 or less, 0.07 or less, 0.06 or less, 0.05 or less, 0.04 or less, 0.03 or less, 0.02 or less, or 0.01 or less). The value of z can range from any of the minimum values described above to any of the maximum values described above. For example, z can be from 0 to 0.2 (e.g., from 0 to 0.1, from 0.1 to 0.2, from 0 to 0.05, from 0.05 to 0.1, from 0.1 to 0.15, from 0.15 to 0.2, from 0 to 0.15, from 0.05 to 0.2, or from 0.05 to 0.15). In some examples, x is 0, such that the second layer comprises Ga₂O₃. In some examples, the second layer comprises β-Ga₂O₃.

The second layer can, for example, have an average thickness of 5 micrometers (microns, μm) or more (e.g., 5.5 μm or more, 6 μm or more, 6.5 μm or more, 7 μm or more, 7.5 μm or more, 8 μm or more, 8.5 μm or more, 9 μm or more, 9.5 μm or more, 10 μm or more, 10.5 μm or more, 11 μm or more, 11.5 μm or more, 12 μm or more, 12.5 μm or more, 13 μm or more, 13.5 μm or more, 14 μm or more, 14.5 μm or more, 15 μm or more, 16 μm or more, 17 μm or more, 18 μm or more, 19 μm or more, 20 μm or more, 25 μm or more, 30 μm or more, 35 μm or more, 40 μm or more, 45 μm or more, 50 μm or more, 60 μm or more, 70 μm or more, 80 μm or more, 90 μm or more, 100 μm or more, 125 μm or more, 150 μm or more, 175 μm or more, 200 μm or more, 225 μm or more, 250 μm or more, 300 μm or more, 350 μm or more, 400 μm or more, 450 μm or more, 500 μm or more, 600 μm or more, 700 μm or more, 800 μm or more, or 900 μm or more). In some examples, the second layer can have an average thickness of 1000 μm or less (e.g., 900 μm or less, 800 μm or less, 700 μm or less, 600 μm or less, 500 μm or less, 450 μm or less, 400 μm or less, 350 μm or less, 300 μm or less, 250 μm or less, 225 μm or less, 200 μm or less, 175 μm or less, 150 μm or less, 125 μm or less, 100 μm or less, 90 μm or less, 80 μm or less, 70 μm or less, 60 μm or less, 50 μm or less, 45 μm or less, 40 μm or less, 35 μm or less, 30 μm or less, 25 μm or less, 20 μm or less, 19 μm or less, 18 μm or less, 17 μm or less, 16 μm or less, 15 μm or less, 14.5 μm or less, 14 μm or less, 13.5 μm or less, 13 μm or less, 12.5 μm or less, 12 μm or less, 11.5 μm or less, 11 μm or less, 10.5 μm or less, 10 μm or less, 9.5 μm or less, 9 μm or less, 8.5 μm or less, 8 μm or less, 7.5 μm or less, 7 μm or less, 6.5 μm or less, or 6 μm or less). The average thickness of the second layer can range from any of the minimum values described above to any of the maximum values described above. For example, the second layer can have an average thickness of from 5 to 1000 μm (e.g., from 5 to 500 μm, from 500 to 1000 μm, from 5 to 200 μm, from 200 to 400 μm, from 400 to 600 μm, from 600 to 800 μm, from 800 to 1000 μm, from 5 to 800 μm, from 5 to 600 μm, from 5 to 400 μm, from 5 to 100 μm, from 5 to 50 μm, from 5 to 25 μm, from 5 to 15 μm, from 10 to 1000 μm, from 15 to 1000 μm, from 25 to 1000 μm, from 50 to 1000 μm, from 100 to 1000 μm, from 200 to 1000 μm, from 400 to 1000 μm, from 600 to 1000 μm, from 10 to 1900 μm, from 15 to 1800 μm, or from 25 to 1500 μm). In some examples, the second layer can have an average thickness of from 5 to 100 μm, the second layer can have an average thickness of from 5 μm to 15 μm (e.g., from 5 to 10 μm, from 10 to 15 μm, from 5 to 7.5 μm, from 7.5 to 10 μm, from 10 to 12.5 μm, from 12.5 to 15 μm, from 5 to 14 μm, from 5 to 13 μm, from 5 to 12 μm, from 5 to 11 μm, from 5 to 9 μm, from 5 to 8 μm, from 5 to 7 μm, from 6 to 15 μm, from 7 to 15 μm, from 8 to 15 μm, from 9 to 15 μm, from 11 to 15 μm, from 12 to 15 μm, from 13 to 15 μm, from 5.5 to 14.5 μm, or from 6 to 9 μm).

For example, disclosed herein are devices comprising a (001) Ga₂O₃ substrate, a first layer comprising (AlₓGa₁₋ₓ)₂O₃ where x is from 0 to 0.5, and a second layer comprising (Al_{z}Ga_{1-z})₂O₃ where z is from 0 to 0.2, wherein the first layer is disposed on the substrate and the second layer is disposed on the first layer, such that the first layer is sandwiched between the substrate and the second layer, wherein the second layer has an average thickness of from 5 μm to 1000 μm.

For example, disclosed herein are devices comprising a (001) Ga₂O₃ substrate, a first layer comprising (AlₓGa₁₋ₓ)₂O₃ where x is from 0 to 0.5, and a second layer comprising Ga₂O₃, wherein the first layer is disposed on the substrate and the second layer is disposed on the first layer, such that the first layer is sandwiched between the substrate and the second layer, wherein the second layer has an average thickness of from 5 μm to 15 μm.

In some examples, the first layer comprises (AlₓGa₁₋ₓ)₂O₃ where x is from 0 to 0.5, the first layer has an average thickness of from 5 to 500 nm, and the second layer has an average thickness of from 5 to 15 μm. In some examples, the first layer comprises (AlₓGa₁₋ₓ)₂O₃ where x is from 0 to 0.5, the first layer has an average thickness of from 10 to 100 nm, and the second layer has an average thickness of from 5 to 15 μm. In some examples, the first layer comprises (AlₓGa₁₋ₓ)₂O₃ where x is from 0 to 0.5, the first layer has an average thickness of from 15 to 25 nm, and the second layer has an average thickness of from 5 to 15 μm.

In some examples, the first layer comprises (AlₓGa₁₋ₓ)₂O₃ where x is from 0 to 0.5, the first layer has an average thickness of from 5 to 500 nm, and the second layer has an average thickness of from 6 to 9 μm. In some examples, the first layer comprises (AlₓGa₁₋ₓ)₂O₃ where x is from 0 to 0.5, the first layer has an average thickness of from 10 to 100 nm, and the second layer has an average thickness of from 6 to 9 μm. In some examples, the first layer comprises (AlₓGa₁₋ₓ)₂O₃ where x is from 0 to 0.5, the first layer has an average thickness of from 15 to 25 nm, and the second layer has an average thickness of from 6 to 9 μm.

In some examples, the first layer comprises (AlₓGa₁₋ₓ)₂O₃ where x is from 0 to 0.3, the first layer has an average thickness of from 5 to 500 nm, and the second layer has an average thickness of from 5 to 15 μm. In some examples, the first layer comprises (AlₓGa₁₋ₓ)₂O₃ where x is from 0 to 0.3, the first layer has an average thickness of from 10 to 100 nm, and the second layer has an average thickness of from 5 to 15 μm. In some examples, the first layer comprises (AlₓGa₁₋ₓ)₂O₃ where x is from 0 to 0.3, the first layer has an average thickness of from 15 to 25 nm, and the second layer has an average thickness of from 5 to 15 μm.

In some examples, the first layer comprises (AlₓGa₁₋ₓ)₂O₃ where x is from 0 to 0.3, the first layer has an average thickness of from 5 to 500 nm, and the second layer has an average thickness of from 6 to 9 μm. In some examples, the first layer comprises (AlₓGa₁₋ₓ)₂O₃ where x is from 0 to 0.3, the first layer has an average thickness of from 10 to 100 nm, and the second layer has an average thickness of from 6 to 9 μm. In some examples, the first layer comprises (AlₓGa₁₋ₓ)₂O₃ where x is from 0 to 0.3, the first layer has an average thickness of from 15 to 25 nm, and the second layer has an average thickness of from 6 to 9 μm.

In some examples, the second layer has a surface roughness that is lower than the surface roughness of the same device in the absence of the first layer.

In some examples, the second layer is relatively smooth and/or substantially free of cracks.

In some examples, the device comprises an optical device, an electronic device, an optoelectronic device, or a combination thereof. In some examples, the device comprises a lateral device, a vertical device, or a combination thereof.

Also disclosed herein are methods of making any of the devices disclosed herein. For example, the methods can comprise depositing the first layer on the substrate and depositing the second layer on the first layer. In some examples, the first layer and/or the second layer are deposited using metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof. In some examples, the first layer and/or the second layer are deposited using metal organic chemical vapor deposition (MOCVD), hydride vapor phase epitaxy (HVPE), low pressure chemical vapor deposition (LPCVD), or a combination thereof. In some examples, the first layer and/or the second layer are deposited using metal organic chemical vapor deposition (MOCVD).

In some examples, the first layer is deposited using MOCVD using an Al-containing precursor, a Ga-containing precursor, an oxygen containing precursor, or a combination thereof. In some examples, the first layer is deposited using MOCVD using an Al-containing precursor, a Ga-containing precursor, and an oxygen containing precursor. In some examples, the concentration of aluminum in the first layer can be controlled by controlling the concentration and/or ratio of the precursors, the temperature, the pressure, or a combination thereof.

In some examples, the method produces the first layer at a growth rate of 100 nanometers per hour (nm/hour) or more (e.g., 125 nm/hour or more, 150 nm/hour or more, 175 nm/hour or more, 200 nm/hour or more, 225 nm/hour or more, 250 nm/hour or more, 275 nm/hour or more, 300 nm/hour or more, 325 nm/hour or more, 350 nm/hour or more, 375 nm/hour or more, 400 nm/hour or more, 425 nm/hour or more, 450 nm/hour or more, 475 nm/hour or more, 500 nm/hour or more, 525 nm/hour or more, 550 nm/hour or more, 575 nm/hour or more, 600 nm/hour or more, 625 nm/hour or more, 650 nm/hour or more, 675 nm/hour or more, 700 nm/hour or more, 725 nm/hour or more, 750 nm/hour or more, 775 nm/hour or more, 800 nm/hour or more, 825 nm/hour or more, 850 nm/hour or more, 875 nm/hour or more, 900 nm/hour or more, 925 nm/hour or more, 950 nm/hour or more, 975 nm/hour or more, 1000 nm/hour or more, 1050 nm/hour or more, 1100 nm/hour or more, 1150 nm/hour or more, 1200 nm/hour or more, 1250 nm/hour or more, 1300 nm/hour or more, 1350 nm/hour or more, 1400 nm/hour or more, 1450 nm/hour or more, 1500 nm/hour or more, 1600 nm/hour or more, 1700 nm/hour or more, 1800 nm/hour or more, or 1900 nm/hour or more). In some examples, the method produces the first layer at a growth rate of 2000 nm/hour or less (e.g., 1900 nm/hour or less, 1800 nm/hour or less, 1700 nm/hour or less, 1600 nm/hour or less, 1500 nm/hour or less, 1450 nm/hour or less, 1400 nm/hour or less, 1350 nm/hour or less, 1300 nm/hour or less, 1250 nm/hour or less, 1200 nm/hour or less, 1150 nm/hour or less, 1100 nm/hour or less, 1050 nm/hour or less, 1000 nm/hour or less, 975 nm/hour or less, 950 nm/hour or less, 925 nm/hour or less, 900 nm/hour or less, 875 nm/hour or less, 850 nm/hour or less, 825 nm/hour or less, 800 nm/hour or less, 775 nm/hour or less, 750 nm/hour or less, 725 nm/hour or less, 700 nm/hour or less, 675 nm/hour or less, 650 nm/hour or less, 625 nm/hour or less, 600 nm/hour or less, 575 nm/hour or less, 550 nm/hour or less, 525 nm/hour or less, 500 nm/hour or less, 475 nm/hour or less, 450 nm/hour or less, 425 nm/hour or less, 400 nm/hour or less, 375 nm/hour or less, 350 nm/hour or less, 325 nm/hour or less, 300 nm/hour or less, 275 nm/hour or less, 250 nm/hour or less, 225 nm/hour or less, 200 nm/hour or less, 175 nm/hour or less, 150 nm/hour or less, or 125 nm/hour or less). The growth rate of the first layer can range from any of the minimum values described above to any of the maximum values described above. For example, the method can produce the first layer at a growth rate of from 100 to 2000 nm/hour (e.g., from 100 to 1000 nm/hour, from 1000 to 2000 nm/hour, from 100 to 450 nm/hour, from 450 to 800 nm/hour, from 800 to 1400 nm/hour, from 1400 to 2000 nm/hour, from 100 to 300 nm/hour, from 300 to 500 nm/hour, from 500 to 800 nm/hour, from 800 to 1000 nm/hour, from 1000 to 1200 nm/hour, from 1200 to 1400 nm/hour, from 1400 to 1600 nm/hour, from 1600 to 1800 nm/hour, from 1800 to 2000 nm/hour, from 100 to 1800 nm/hour, from 100 to 1600 nm/hour, from 100 to 1400 nm/hour, from 100 to 1200 nm/hour, from 100 to 800 nm/hour, from 100 to 700 nm/hour, from 100 to 600 nm/hour, from 100 to 500 nm/hour, from 100 to 400 nm/hour, from 100 to 200 nm/hour, from 200 to 2000 nm/hour, from 300 to 2000 nm/hour, from 400 to 2000 nm/hour, from 500 to 2000 nm/hour, from 600 to 2000 nm/hour, from 700 to 2000 nm/hour, from 800 to 2000 nm/hour, from 1200 to 2000 nm/hour, from 1400 to 2000 nm/hour, from 1600 to 2000 nm/hour, from 200 to 1800 nm/hour, from 300 to 1600 nm/hour, from 200 to 800 nm/hour, from 300 to 800 nm/hour, from 400 to 800 nm/hour, from 600 to 800 nm/hour, from 700 to 800 nm/hour, from 150 to 750 nm/hour, from 200 to 600 nm/hour, or from 350 to 450 nm/hour). In some examples, the method can produce the first layer at a growth rate of from 100 to 800 nm/hour. In some examples, the method can produce the first layer at a growth rate of 400 nm/hour.

In some examples, the second layer is deposited using MOCVD using an Al-containing precursor, a Ga-containing precursor, an oxygen containing precursor, or a combination thereof. In some examples, the second layer is deposited using MOCVD using a Ga-containing precursor and an oxygen containing precursor.

In some examples, the method produces the second layer at a growth rate of 1 μm/hour or more (e.g., 1.5 μm/hour or more, 2 μm/hour or more, 2.5 μm/hour or more, 3 μm/hour or more, 3.5 μm/hour or more, 4 μm/hour or more, 4.5 μm/hour or more, 5 μm/hour or more, 5.5 μm/hour or more, 6 μm/hour or more, 6.5 μm/hour or more, 7 μm/hour or more, 7.5 μm/hour or more, 8 μm/hour or more, 8.5 μm/hour or more, 9 μm/hour or more, 9.5 μm/hour or more, 10 μm/hour or more, 10.5 μm/hour or more, 11 μm/hour or more, 11.5 μm/hour or more, 12 μm/hour or more, 12.5 μm/hour or more, 13 μm/hour or more, 13.5 μm/hour or more, 14 μm/hour or more, 14.5 μm/hour or more, 15 μm/hour or more, 15.5 μm/hour or more, 16 μm/hour or more, 16.5 μm/hour or more, 17 μm/hour or more, 17.5 μm/hour or more, 18 μm/hour or more, 18.5 μm/hour or more, or 19 μm/hour or more). In some examples, the method produces the second layer at a growth rate of 20 μm/hour or less (e.g., 19.5 μm/hour or less, 19 μm/hour or less, 18.5 μm/hour or less, 18 μm/hour or less, 17.5 μm/hour or less, 17 μm/hour or less, 16.5 μm/hour or less, 16 μm/hour or less, 15.5 μm/hour or less, 15 μm/hour or less, 14.5 μm/hour or less, 14 μm/hour or less, 13.5 μm/hour or less, 13 μm/hour or less, 12.5 μm/hour or less, 12 μm/hour or less, 11.5 μm/hour or less, 11 μm/hour or less, 10.5 μm/hour or less, 10 μm/hour or less, 9.5 μm/hour or less, 9 μm/hour or less, 8.5 μm/hour or less, 8 μm/hour or less, 7.5 μm/hour or less, 7 μm/hour or less, 6.5 μm/hour or less, 6 μm/hour or less, 5.5 μm/hour or less, 5 μm/hour or less, 4.5 μm/hour or less, 4 μm/hour or less, 3.5 μm/hour or less, 3 μm/hour or less, 2.5 μm/hour or less, or 2 μm/hour or less). The growth rate of the second layer can range from any of the minimum values described above to any of the maximum values described above. For example, the method can produce the second layer at a growth rate of from 1 to 20 μm/hour (e.g., from 1 to 10 μm/hour, from 10 to 20 μm/hour, from 1 to 5 μm/hour, from 5 to 10 μm/hour, from 10 to 15 μm/hour, from 15 to 20 μm/hour, from 1 to 4 μm/hour, from 4 to 7 μm/hour, from 7 to 10 μm/hour, from 10 to 13 μm/hour, from 13 to 16 μm/hour, from 16 to 20 μm/hour, from 1 to 18 μm/hour, from 1 to 16 μm/hour, from 1 to 14 μm/hour, from 1 to 12 μm/hour, from 1 to 9 μm/hour, from 1 to 8 μm/hour, from 1 to 7 μm/hour, from 1 to 6 μm/hour, from 1 to 3 μm/hour, from 2 to 20 μm/hour, from 3 to 20 μm/hour, from 4 to 20 μm/hour, from 5 to 20 μm/hour, from 6 to 20 μm/hour, from 7 to 20 μm/hour, from 8 to 20 μm/hour, from 9 to 20 μm/hour, from 12 to 20 μm/hour, from 14 to 20 μm/hour, from 16 to 20 μm/hour, from 18 to 20 μm/hour, from 2 to 18 μm/hour, from 3 to 17 μm/hour, from 5 to 15 μm/hour, from 2 to 10 μm/hour, from 3 to 10 μm/hour, from 4 to 10 μm/hour, from 6 to 10 μm/hour, from 8 to 10 μm/hour, from 1.5 to 9.5 μm/hour, from 2 to 6 μm/hour, from 2 to 4 μm/hour, or from 2.5 to 3.5 μm/hour). In some examples, the method can produce the second layer at a growth rate of from 1 to 10 μm/hour. In some examples, the method can produce the second layer at a growth rate of 3 μm/hour.

In some examples, the Al-containing precursor, the Ga-containing precursor, and/or the oxygen containing precursor independently comprise(s) a fluid, such as a gas.

In some examples, the Al-containing precursor comprises trimethylaluminum (TMAl), triethyl aluminum (TEAl), or a combination thereof. In some examples, the Al-containing precursor comprises trimethylaluminum (TMAl).

In some examples, the Ga-containing precursor comprises trimethylgallium (TMGa), triethyl gallium (TEGa), or a combination thereof.

In some examples, the oxygen containing precursor comprises 02.

In some examples, the method further comprises introducing an additional precursor comprising a dopant, such that the first layer and/or the second layer further comprises the dopant. In some examples, the additional precursor is provided as a fluid, such as a gas. In some examples, the additional precursor comprises an n-type dopant, such as a silicon containing precursor.

In some examples, the Al-containing precursor, the Ga-containing precursor, the oxygen containing precursor, the additional precursor (when present), or a combination thereof are independently provided with a carrier gas. In some examples, the carrier gas comprises argon, helium, N₂, and the like, or combinations thereof.

In some examples, the method is conducted at a temperature of 650° C. or more (e.g., 675° C. or more, 700° C. or more, 725° C. or more, 750° C. or more, 775° C. or more, 800° C. or more, 825° C. or more, 850° C. or more, 875° C. or more, 900° C. or more, 925° C. or more, 950° C. or more, 975° C. or more, 1000° C. or more, 1025° C. or more, 1050° C. or more, or 1075° C. or more). In some examples, the temperature is 1100° C. or less (e.g., 1075° C. or less, 1050° C. or less, 1025° C. or less, 1000° C. or less, 975° C. or less, 950° C. or less, 925° C. or less, 900° C. or less, 875° C. or less, 850° C. or less, 825° C. or less, 800° C. or less, 775° C. or less, 750° C. or less, 725° C. or less, 700° C. or less, or 675° C. or less). The temperature can range from any of the minimum values described above to any of the maximum values described above. For example, the temperature can be from 650° C. to 1100° C. (e.g., from 650° C. to 875° C., from 875° C. to 1100° C., from 650° C. to 750° C., from 750° C. to 850° C., from 850° C. to 950° C., from 950° C. to 1100° C., from 650° C. to 1000° C., from 650° C. to 900° C., from 650° C. to 825° C., from 650° C. to 800° C., from 750° C. to 1100° C., from 850° C. to 1100° C., from 900° C. to 1100° C., from 675° C. to 1075° C., from 700° C. to 1000° C., from 750° C. to 1000° C., from 825° C. to 1000° C., from 850° C. to 1000° C., from 900° C. to 1000° C., from 950° C. to 1000° C., from 675° C. to 975° C., or from 700° C. to 950° C.). In some examples, the temperature can be from 650° C. to 1000° C.

In some examples, the method is conducted at a pressure of 5 torr or more (e.g., 10 torr or more, 15 torr or more, 20 torr or more, 25 torr or more, 30 torr or more, 35 torr or more, 40 torr or more, 45 torr or more, 50 torr or more, 60 torr or more, 70 torr or more, 80 torr or more, 90 torr or more, 100 torr or more, 125 torr or more, 150 torr or more, 175 torr or more, 200 torr or more, 225 torr or more, 250 torr or more, 300 torr or more, 350 torr or more, 400 torr or more, 450 torr or more, 500 torr or more, or 550 torr or more). In some examples, the pressure is 600 torr or less (e.g., 550 torr or less, 500 torr or less, 450 torr or less, 400 torr or less, 350 torr or less, 300 torr or less, 250 torr or less, 225 torr or less, 200 torr or less, 175 torr or less, 150 torr or less, 125 torr or less, 100 torr or less, 90 torr or less, 80 torr or less, 70 torr or less, 60 torr or less, 50 torr or less, 45 torr or less, 40 torr or less, 35 torr or less, 30 torr or less, 25 torr or less, 20 torr or less, 15 torr or less, or 10 torr or less). The pressure can range from any of the minimum values described above to any of the maximum values described above. For example, the pressure can be from 5 to 600 torr (e.g., from 5 to 300 torr, from 300 to 600 torr, from 5 to 200 torr, from 200 to 400 torr, from 400 to 600 torr, from 5 to 500 torr, from 5 to 400 torr, from 5 to 100 torr, from 5 to 50 torr, from 5 to 25 torr, from 25 to 600 torr, from 50 to 600 torr, from 100 to 600 torr, from 200 to 600 torr, from 500 to 600 torr, from 10 to 550 torr, or from 25 to 500 torr).

In some examples, the method is conducted at a temperature of from 650-1000° C. and/or a pressure of from 5 to 600 torr.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the devices and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1—Method for Developing Thick β-Ga₂O₃ Films on (001) Ga₂O₃ Substrates Using (AlₓGa₁₋ₓ)₂O₃ Buffer Layer

Owing to its remarkable properties, such as a large energy bandgap (4.8 eV), controllable n-type doping, and a high predicted breakdown field strength (8 MV/cm), β-Ga₂O₃ is regarded as a promising semiconductor material for next-generation high-power electronic devices [1]. Another significant advantage of β-Ga₂O₃ over other wide bandgap (GaN, SiC) and ultra-wide bandgap (diamond, AlN) materials is the availability of high-quality, single-crystal native substrates with various orientations, grown using cost-effective, scalable melt growth techniques [2].

In recent years, significant progress in the development of β-Ga₂O₃-based lateral and vertical devices has been demonstrated for high-voltage and high-power electronic applications. Recently, a lateral β-Ga₂O₃ Schottky barrier diode (SBD) with a high permittivity (high-k) dielectric superjunction (SJ) structure has been demonstrated with a high breakdown voltage of 1.487 KV and a Power Figure of Merit (PFOM) of 1.34 GW/cm² [3]. On the other hand, β-Ga₂O₃ vertical rectifiers utilizing planar or trench metal-oxide-semiconductor (MOS) techniques have been reported with breakdown voltages greater than 2 kV, making them an attractive approach due to their larger current-carrying capacity in vertical geometry devices [4,5]. β-Ga₂O₃ vertical Schottky barrier diodes with a staircase field plate on a deep trench filled with SiO₂ were successfully demonstrated with superior device characteristics, such as an on-resistance of 7.6 mΩ cm² and an off-state breakdown voltage of 1.66 kV [6]. A breakdown voltage of 2.89 kV and Baliga's figure-of-merit (BFOM) of 0.80 GW/cm² (BV²/R_{on,sp}) was achieved from SBDs utilizing vertical fin structure [4]. Very recently, record high breakdown voltage of up to 6 kV and a low on-resistance of 3.4 mΩ cm² have been reported for β-Ga₂O₃ vertical Schottky barrier diodes by utilizing a vertical structure with a deep trench of SiO₂ to provide edge termination, leading to a record high Baliga's power figure of merit ranging from 7.4-10.6 GW/cm² [7]. Due to the lack of shallow p-type dopants in β-Ga₂O₃, the integration of n-type Ga₂O₃ with p-type NiO for vertical PN heterojunction power diodes has resulted in lower leakage current and on-resistance than conventional planar rectifiers [8,9]. For example, β-Ga₂O₃/NiO heterojunction PN diodes have been demonstrated with a record high breakdown voltage of 8.32 kV, specific on-resistance of 5.24 mΩ·cm², power figure-of-merit of 13.2 GW/cm², and turn-on voltage of 1.8 V [9]. The power figure-of-merit value of β-Ga₂O₃/NiO heterojunction PN diodes has already surpassed the 1-D unipolar limit of GaN and SiC [9], indicating immense potential of β-Ga₂O₃ based vertical devices for higher-voltage applications in power electronics.

In order to develop high-power electronic devices with even higher reverse breakdown voltage, a thick drift layer with smooth surface morphology and controllable low doping are needed. Therefore, growth of high quality thick β-Ga₂O₃ with relatively fast growth rates is needed. Although relatively fast growth rates for epitaxial β-Ga₂O₃ layers on (010) oriented β-Ga₂O₃ substrates have been demonstrated using various methods, such as low-pressure chemical vapor deposition (LPCVD) [10] and metal-organic chemical vapor deposition (MOCVD) [11], the growth of thick films often results in three-dimensional (3D) island structures on the growth surface, which is not desirable for device fabrication. Prior research on MOCVD homoepitaxial growth of (100) β-Ga₂O₃ on on-axis β-Ga₂O₃ substrates revealed stacking fault and twin lamellae formation in the epitaxial film [12]. While introducing suitable miscut angles on the substrates allows for step-flow growth of β-Ga₂O₃ thin films on the (100) plane, growth rates on this plane were found to be considerably slower than that on the (010) plane [13], suggesting challenges in developing a thick β-Ga₂O₃ drift layer on (100) oriented β-Ga₂O₃ substrates.

The (001) oriented β-Ga₂O₃ substrates have been primarily used for homoepitaxial growth of β-Ga₂O₃ films with high growth rates (>10 m/h) via halide vapor-phase epitaxy (HVPE) [14]. Majority of the reported vertical β-Ga₂O₃ devices, such as Schottky barrier diode, p-n heterojunction, or metal-insulator-semiconductor (MIS) diode, have been fabricated on (001) oriented β-Ga₂O₃ films. However, HVPE growth at fast growth rates tends to result in significant surface roughness, including surface steps and pits [15, 16], necessitating a chemical-mechanical polishing (CMP) process for device fabrication. The CMP process can cause impurity incorporation and also limits the possibility for developing in-situ heterostructures.

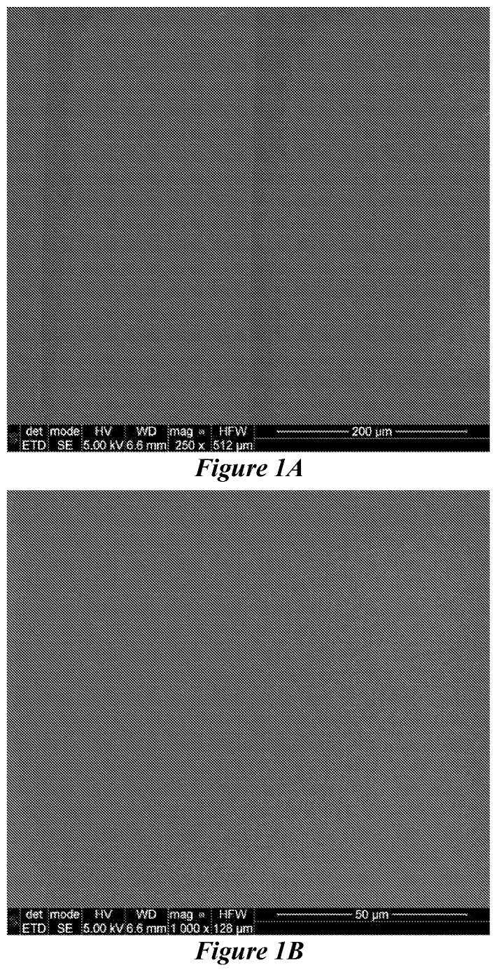

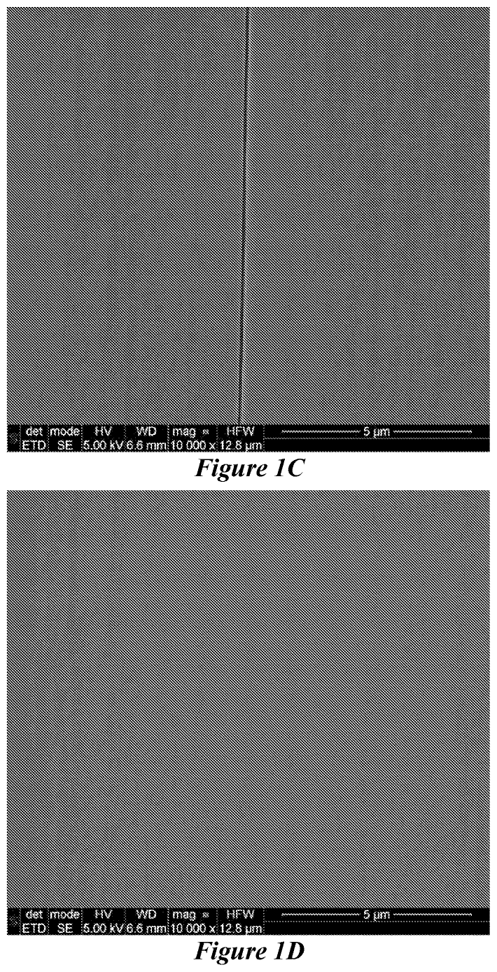

Recently, using trimethylgallium (TMGa) as the Ga precursor, MOCVD growth of high-quality β-Ga₂O₃ thin films on (001) oriented on-axis β-Ga₂O₃ substrates at a fast growth rate of 3 m/hr was demonstrated. Surface morphology was very smooth across the sample, which is very different from the case of using (010) β-Ga₂O₃ substrates [11]. However, one different issue occurs for the MOCVD growth of β-Ga₂O₃ on the (001) Ga₂O₃ substrates; that is the epi-films form cracking across the surface. This issue becomes more severe when the film thickness increases. FIG. 1A-FIG. 1D shows the typical surface morphology of the MOCVD grown (001) β-Ga₂O₃ film. The surface remains very smooth between the cracking lines. In this particular example, the (001) epi-layer was grown at a growth rate of 3 m/h with a film thickness of 9 m. Therefore, it is important to address the surface cracking issue of epitaxy of β-Ga₂O₃ on (001) Ga₂O₃ substrates. Addressing this issue will carry great promise to pave a new way to achieve high performance vertical power devices based on the ultrawide bandgap 3-Ga₂O₃ material.

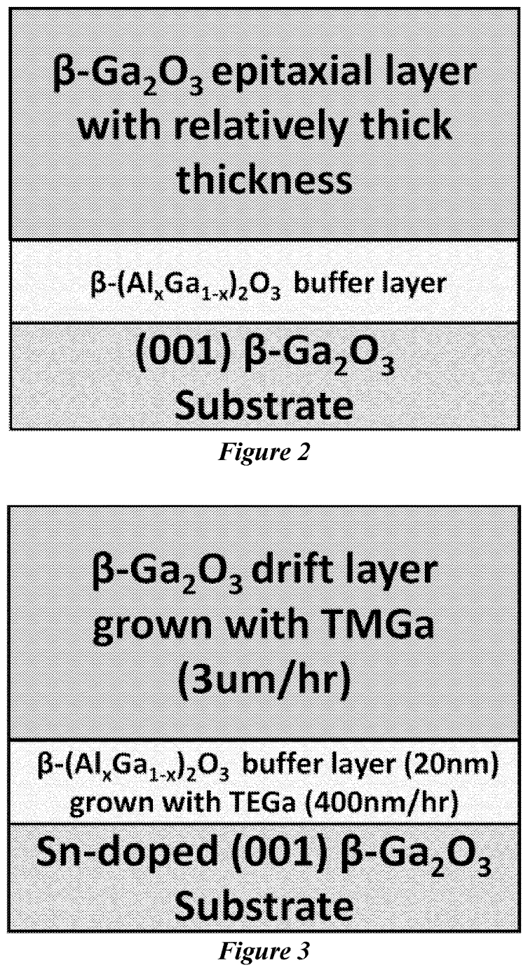

Herein, a technique is described for developing thick β-Ga₂O₃ film on top of (001) Ga₂O₃ substrates by inserting a thin β-(AlₓGa₁₋ₓ)₂O₃ buffer layer, as shown in FIG. 2. The Al composition can be varied between 0% and 50% or so, and the thickness of the buffer layer can be varied between several nanometers and hundreds of nanometers. The AlGaO buffer layer can suppress the cracking of the top β-Ga₂O₃ epi-layer, particularly when the Ga₂O₃ layer is grown at relatively fast growth rate with relatively thick thickness.

In an example of MOCVD growth of (001) β-Ga₂O₃ on top of (001) Ga₂O₃ substrate, the impact of different Al compositions in the β-(AlₓGa₁₋ₓ)₂O₃ buffer layer on the growth of the (001) β-Ga₂O₃ film was investigated. The thickness of the β-(AlₓGa₁₋ₓ)₂O₃ buffer layer is ~20 nm. The cross-sectional schematic is shown in FIG. 3. For the MOCVD growth of the thin β-(AlₓGa₁₋ₓ)₂O₃ buffer layer, the triethylgallium (TEGa), trimethylaluminum (TMAl), and pure O₂ were used as Ga, Al, and O precursors, respectively. Argon (Ar) was used as the carrier gas. Phase pure β-(AlₓGa₁₋ₓ)₂O₃ thin films with varying Al compositions can be achieved through systematically adjusting the VI/III molar ratio, temperature, and chamber pressure. For the top β-Ga₂O₃ layer growth, TMGa was utilized as the Ga precursor, and Ar was used as the carrier gas. The typical growth temperature ranges between 650-1000° C., while the typical chamber pressure varies from 5 to 600 torr. A silicon donor can be employed as an effective n-type dopant in the MOCVD-grown β-Ga₂O₃ and β-(AlₓGa₁₋ₓ)₂O₃ films.

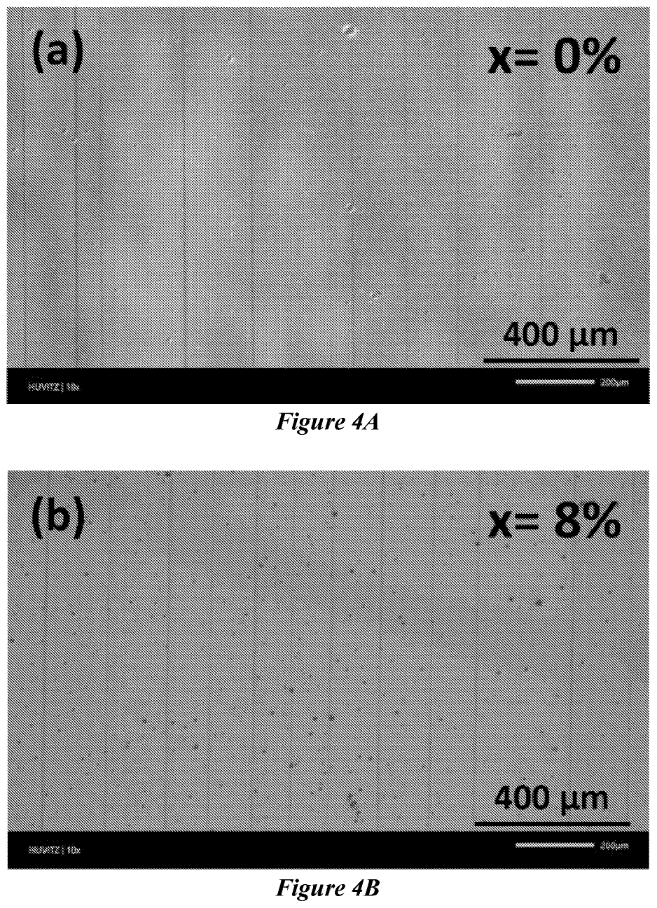

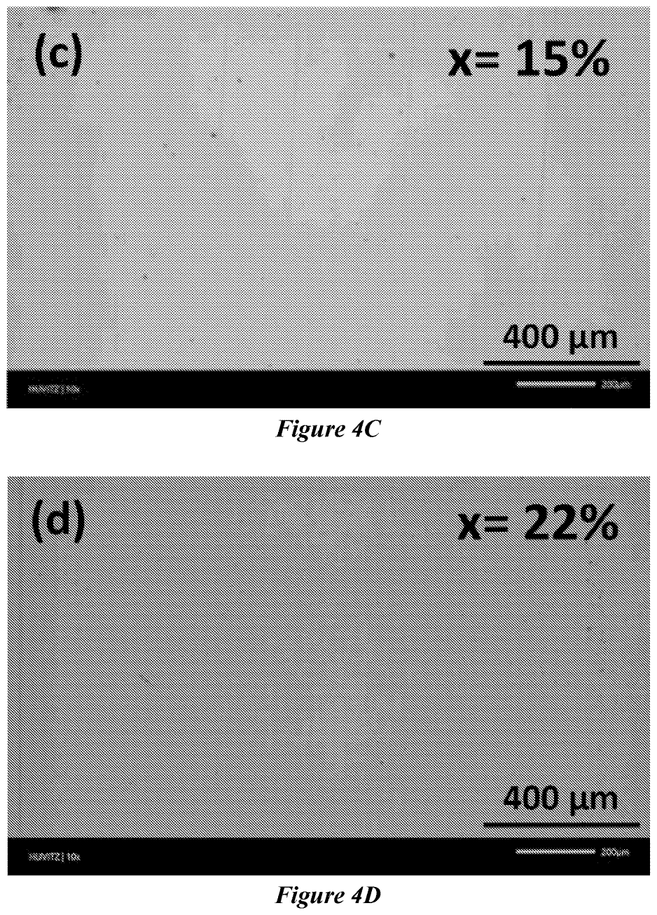

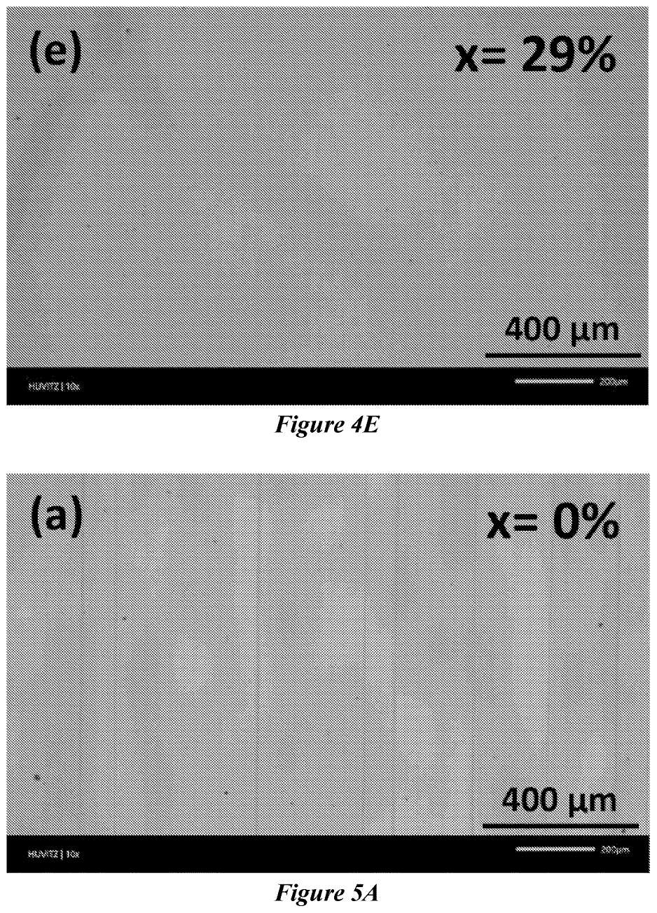

In this example, the thin β-(AlₓGa₁₋ₓ)₂O₃ buffer layer (20 nm) was grown with a low growth rate (400 nm/hr) prior the thick β-Ga₂O₃ layer (6 μm) growth with a high growth rate (3 m/hr). FIG. 4A-FIG. 4E shows the low-magnitude optical macroscopic surface images of β-Ga₂O₃ films grown using TMGa on (001) β-Ga₂O₃ substrates with thin β-(AlₓGa₁₋ₓ)₂O₃ buffer layers of different Al compositions. As the Al composition increases from 0% to 29%, the density of cracks decreases. Note that, for the sample with a 29% β-(AlₓGa₁₋ₓ)₂O₃ buffer layer, there are only 2 cracks on the 5×5 mm² β-Ga₂O₃ epi-film, representing a significant improvement.

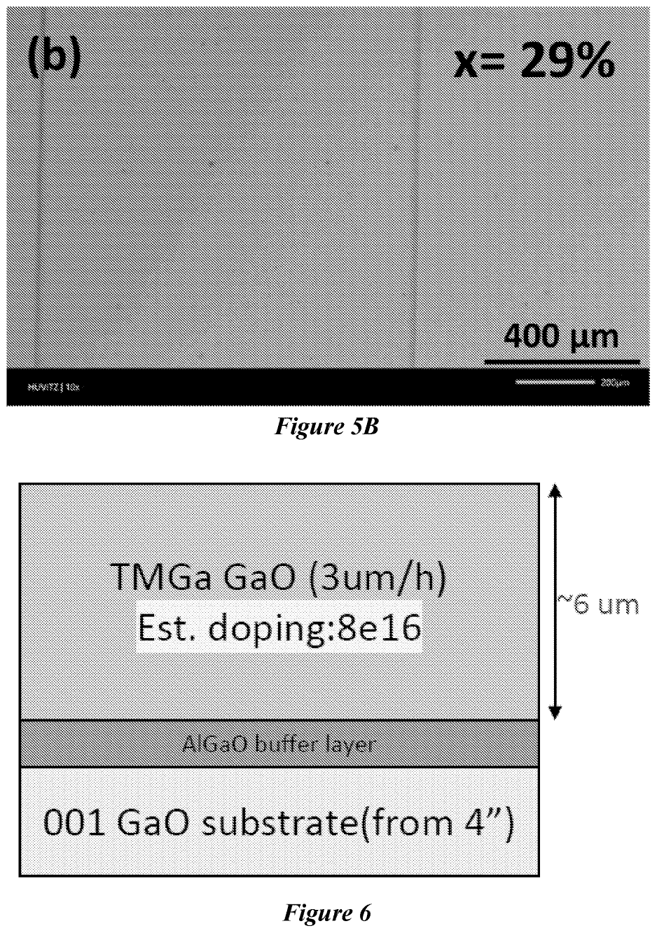

A similar trend was observed for the case of β-Ga₂O₃ film (9 μm) grown with TMGa on (001) β-Ga₂O₃ substrates with a thin β-(AlₓGa₁₋ₓ)₂O₃ layer. As shown in FIG. 5A-FIG. 5B, the surface of the 9 μm β-Ga₂O₃ film with a 29% β-(AlₓGa₁₋ₓ)₂O₃ buffer layer exhibits a much lower crack density as compared to the one without a buffer layer.

For device applications, the thickness and Al composition of the β-(AlₓGa₁₋ₓ)₂O₃ buffer layer can be optimized for a targeted β-Ga₂O₃ film growth rate and total layer thickness.

### REFERENCES

1. A. J. Green et al. APL Mater. 10, 029201 (2022).
2. A. Kuramata et al. Jpn. J. Appl. Phys. 55, 1202A2 (2016).
3. S. Roy et al. IEEE Electron Device Lett. 43(12), 2037 (2022).
4. W. Li et al. IEEE Electron Device Lett. 41, 107 (2020).
5. J. Yang et al. ECS J. Solid State Sci. Technol. 7, Q92 (2018).
6. S. Kumar et al. Appl. Phys. Express 15, 054001 (2022).
7. P. Dong et al. IEEE Electron Device Lett. 43(5), 765 (2022).
8. J.-S. Li et al. Appl. Phys. Lett. 121, 042105 (2022).
9. J. Zhang et al. Nat. Commun. 13, 3900 (2022).
10. Y. Zhang et al. J. Vac. Sci. Technol. A 38, 050806 (2020).
11. L. Meng et al. Cryst. Growth Des. 22, 3896 (2022).
12. R. Schewski et al. J. Appl. Phys. 120, 225308 (2016).
13. S. Bin Anooz et al. Appl. Phys. Lett. 116, 182106 (2020).
14. Z. Hu et al. IEEE Electron Device Lett. 39, 1564 (2018).
15. H. Murakami et al. Appl. Phys. Express 8, 015503 (2014).
16. J. H. Leach et al. APL Mater. 7, 022504 (2019).

### Example 2

A schematic diagram of a (001) Ga₂O₃ 6 μm-thick film grown on an AlGaO buffer layer on a (001) GaO substrate is shown in FIG. 6.

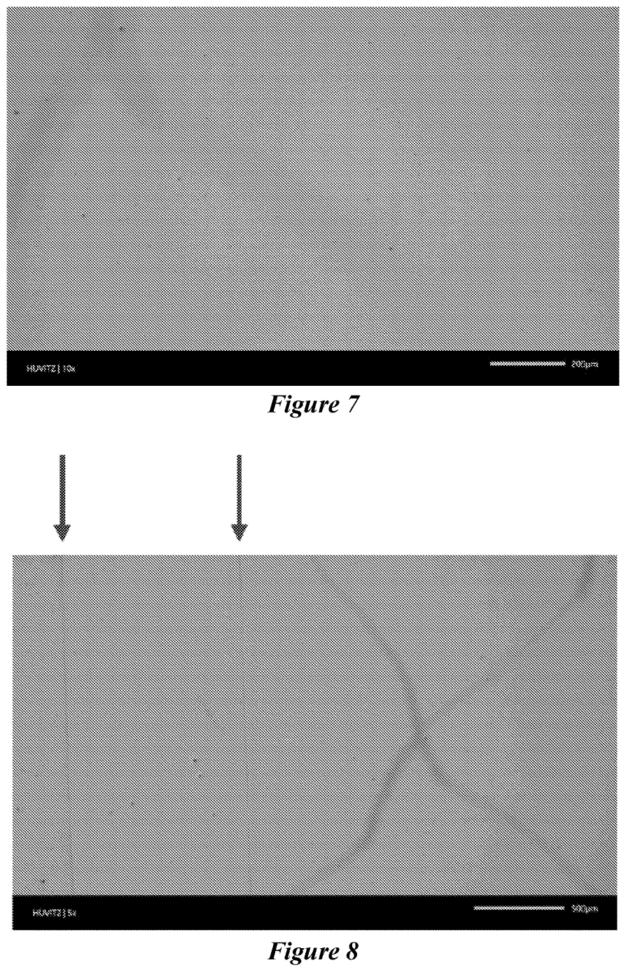

Optical images of the Ga₂O₃ film are shown in FIG. 7 and FIG. 8, with only two cracks being observed in the sample (indicated with arrows in FIG. 8), which were concentrated on one side.

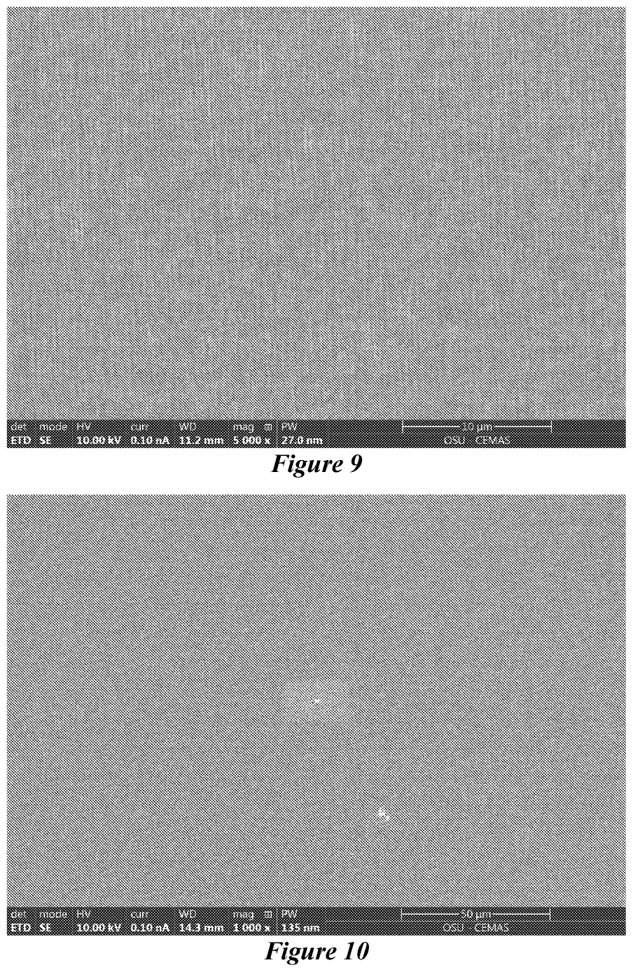

SEM images of the Ga₂O₃ film are shown in FIG. 9 and FIG. 10.

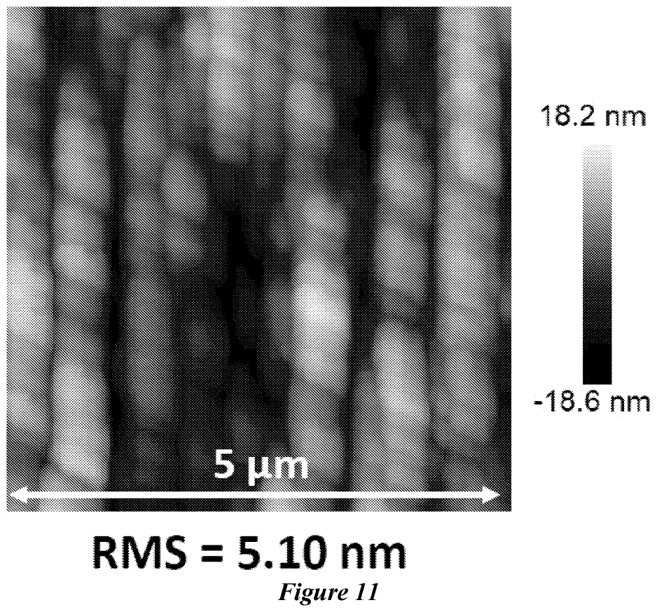

AFM was used to further analyze the surface (FIG. 11).

### EXEMPLARY ASPECTS

In view of the described compositions, devices, systems, and methods, herein below are described certain more particularly described aspects of the inventions. The particularly recited aspects should not, however, be interpreted to have any limiting effect on any different claims containing different or more general teachings described herein or that the “particular” aspects are somehow limited in some way other than the inherent meanings of the language and formulas literally used therein.

Example 1: A device comprising a (001) Ga₂O₃ substrate, a first layer comprising (AlₓGa₁₋ₓ)₂O₃ where x is from 0 to 0.5, and a second layer comprising (Al_{z}Ga_{1-z})₂O₃ where z is from 0 to 0.2, wherein the first layer is disposed on the substrate and the second layer is disposed on the first layer, such that the first layer is sandwiched between the substrate and the second layer, wherein the second layer has an average thickness of from 5 μm to 1000 μm.

Example 2: The device of any examples herein, particularly example 1, wherein the substrate comprises a (001) β-Ga₂O₃ substrate.

Example 3: The device of any examples herein, particularly example 1 or example 2, wherein the first layer comprises (AlₓGa₁₋ₓ)₂O₃ where x is from 0 to 0.3.

Example 4: The device of any examples herein, particularly examples 1-3, wherein the first layer has an average thickness of from 5 to 1000 nm, from 5 nm to 500 nm, from 10 nm to 100 nm, or from 15 to 25 nm.

Example 5: The device of any examples herein, particularly examples 1-4, wherein the second layer comprises Ga₂O₃.

Example 6: The device of any examples herein, particularly examples 1-5, wherein the second layer comprises β-Ga₂O₃.

Example 7: The device of any examples herein, particularly examples 1-6, wherein the second layer has an average thickness of from 5 to 100 μm.

Example 8: The device of any examples herein, particularly examples 1-7, wherein the second layer has an average thickness of from 5 to 15 μm.

Example 9: The device of any examples herein, particularly examples 1-8, wherein the second layer has an average thickness of from 6 to 9 μm.

Example 10: The device of any examples herein, particularly examples 1-9, wherein the device comprises a (001) Ga₂O₃ substrate, a first layer comprising (AlₓGa₁₋ₓ)₂O₃ where x is from 0 to 0.5, and a second layer comprising Ga₂O₃, wherein the first layer is disposed on the substrate and the second layer is disposed on the first layer, such that the first layer is sandwiched between the substrate and the second layer, wherein the second layer has an average thickness of from 5 μm to 15 μm.

Example 11: The device of any examples herein, particularly examples 1-10, wherein the second layer has a surface roughness that is lower than the surface roughness of the same device in the absence of the first layer.

Example 12: The device of any examples herein, particularly examples 1-11, wherein the second layer is relatively smooth and/or substantially free of cracks.

Example 13: The device of any examples herein, particularly examples 1-12, wherein the device comprises an optical device, an electronic device, an optoelectronic device, or a combination thereof.

Example 14: The device of any examples herein, particularly examples 1-13, wherein the device comprises a lateral device, a vertical device, or a combination thereof.

Example 15: A method of making the device of any examples herein, particularly examples 1-14, the method comprising depositing the first layer on the substrate and depositing the second layer on the first layer.

Example 16: The method of any examples herein, particularly example 15, wherein the first layer and/or the second layer are deposited using metal organic chemical vapor deposition (MOCVD).

Example 17: The method of any examples herein, particularly example 15 or example 16, wherein the first layer is deposited using MOCVD using an Al-containing precursor, a Ga-containing precursor, an oxygen containing precursor, or a combination thereof.

Example 18: The method of any examples herein, particularly examples 15-17, wherein the first layer is deposited using MOCVD using an Al-containing precursor, a Ga-containing precursor, and an oxygen containing precursor.

Example 19: The method of any examples herein, particularly example 17 or example 18, wherein the concentration of aluminum in the first layer can be controlled by controlling the concentration and/or ratio of the precursors, the temperature, the pressure, or a combination thereof.

Example 20: The method of any examples herein, particularly examples 15-19, wherein the method produces the first layer at a growth rate of from 100 to 2000 nm/hour.

Example 21: The device of any examples herein, particularly examples 15-20, wherein the method produces the first layer at a growth rate of from 100 to 800 nm/hour, such as 400 nm/hr.

Example 22: The method of any examples herein, particularly examples 15-21, wherein the second layer is deposited using MOCVD using an Al-containing precursor, a Ga-containing precursor, an oxygen containing precursor, or a combination thereof.

Example 23: The device of any examples herein, particularly examples 15-22, wherein the second layer is deposited using MOCVD using a Ga-containing precursor and an oxygen containing precursor.

Example 24: The method of any examples herein, particularly examples 15-23, wherein the method produces the second layer at a growth rate of from 1 to 20 μm/hour.

Example 25: The device of any examples herein, particularly examples 15-24, wherein the method produces the second layer at a growth rate of from 1 to 10 μm/hour, such as 3 μm/hour.

Example 26: The method of any examples herein, particularly examples 17-25, wherein the Al-containing precursor, the Ga-containing precursor, and/or the oxygen containing precursor independently comprise(s) a fluid, such as a gas.

Example 27: The method of any examples herein, particularly examples 17-26, wherein the Al-containing precursor comprises trimethyl aluminum (TMAl), triethyl aluminum (TEAl), or a combination thereof.

Example 28: The method of any examples herein, particularly examples 17-27, wherein the Al-containing precursor comprises trimethylaluminum (TMAl).

Example 29: The method of any examples herein, particularly examples 17-28, wherein the Ga-containing precursor comprises trimethylgallium (TMGa), triethyl gallium (TEGa), or a combination thereof.

Example 30: The method of any examples herein, particularly examples 17-29, wherein the oxygen containing precursor comprises 02.

Example 31: The method of any examples herein, particularly examples 17-30, wherein the method further comprises introducing an additional precursor comprising a dopant, such that the first layer and/or the second layer further comprises the dopant.

Example 32: The method of any examples herein, particularly example 31, wherein the additional precursor is provided as a fluid, such as a gas.

Example 33: The method of any examples herein, particularly example 31 or example 32, wherein the additional precursor comprises an n-type dopant, such as a silicon containing precursor.

Example 34: The method of any examples herein, particularly examples 17-33, wherein the Al-containing precursor, the Ga-containing precursor, the oxygen containing precursor, the additional precursor (when present), or a combination thereof are independently provided with a carrier gas.

Example 35: The method of any examples herein, particularly example 34, wherein the carrier gas comprises argon, helium, N₂, and the like, or combinations thereof.

Example 36: The method of any examples herein, particularly examples 15-35, wherein the method is conducted at a temperature of from 650-1100° C. and/or a pressure of from 5 to 600 torr.

Example 37: The method of any examples herein, particularly examples 15-36, wherein the method is conducted at a temperature of from 650-1000° C. and/or a pressure of from 5 to 600 torr.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A device comprising a (001) Ga₂O₃ substrate, a first layer comprising (AlₓGa₁₋ₓ)₂O₃ where x is from 0 to 0.5, and a second layer comprising (Al_{z}Ga_{1-z})₂O₃ where z is from 0 to 0.2, wherein the first layer is disposed on the substrate and the second layer is disposed on the first layer, such that the first layer is sandwiched between the substrate and the second layer, wherein the second layer has an average thickness of from 5 μm to 1000 μm.

2. The device of claim 1, wherein the substrate comprises a (001) β-Ga₂O₃ substrate.

3. The device of claim 1, wherein the first layer comprises (AlₓGa₁₋ₓ)₂O₃ where x is from 0 to 0.3.

4. The device of claim 1, wherein the first layer has an average thickness of from 5 to 1000 nm.

5. The device of claim 1, wherein the second layer comprises Ga₂O₃.

6. (canceled)

7. The device of claim 1, wherein the second layer has an average thickness of from 5 to 100 μm.

8. The device of claim 1, wherein the second layer has an average thickness of from 5 to 15 μm.

9. (canceled)

10. The device of claim 1, wherein the device comprises a (001) Ga₂O₃ substrate, a first layer comprising (AlₓGa₁₋ₓ)₂O₃ where x is from 0 to 0.5, and a second layer comprising Ga₂O₃, wherein the first layer is disposed on the substrate and the second layer is disposed on the first layer, such that the first layer is sandwiched between the substrate and the second layer, wherein the second layer has an average thickness of from 5 μm to 15 μm.

11. The device of claim 1, wherein the second layer has a surface roughness that is lower than the surface roughness of the same device in the absence of the first layer.

12. The device of claim 1, wherein the second layer is relatively smooth and/or substantially free of cracks.

13. The device of claim 1, wherein the device comprises an optical device, an electronic device, an optoelectronic device, or a combination thereof.

14. The device of claim 1, wherein the device comprises a lateral device, a vertical device, or a combination thereof.

15. A method of making the device of claim 1, the method comprising depositing the first layer on the substrate and depositing the second layer on the first layer.

16. The method of claim 15, wherein the first layer and/or the second layer are deposited using metal organic chemical vapor deposition (MOCVD).

17. The method of claim 15, wherein the first layer is deposited using MOCVD using an Al-containing precursor, a Ga-containing precursor, an oxygen containing precursor, or a combination thereof.

18. (canceled)

19. (canceled)

20. The method of claim 15, wherein the method produces the first layer at a growth rate of from 100 to 2000 nm/hour.

21. (canceled)

22. The method of claim 15, wherein the second layer is deposited using MOCVD using an Al-containing precursor, a Ga-containing precursor, an oxygen containing precursor, or a combination thereof.

23. (canceled)

24. The method of claim 15, wherein the method produces the second layer at a growth rate of from 1 to 20 μm/hour.

25.-30. (canceled)

31. The method of claim 16, wherein the method further comprises introducing an additional precursor comprising a dopant, such that the first layer and/or the second layer further comprises the dopant.

32.-35. (canceled)

36. The method of claim 15, wherein the method is conducted at a temperature of from 650-1100° C. and/or a pressure of from 5 to 600 torr.

37. (canceled)
